(19) United States
(12) Patent Application Publication
(10) Pub. No.: US 2026/0282250 A1
(43) Pub. Date: Sep. 17, 2026

(54) ELECTRONIC DEVICE AND FIXTURE FOR ASSEMBLY AND REPAIR

(71) Applicant: InnoLux Corporation, Miao-Li County (TW)

(72) Inventors: Hung-Ming HSIEH, Miao-Li County (TW); Yi-An CHEN, Miao-Li County (TW); Chih-Hung CHUNG, Miao-Li County (TW)

(73) Assignee: InnoLux Corporation, Miao-Li County (TW)

(21) Appl. No.: 19/380,917

(22) Filed: Nov. 5, 2025

(30) Foreign Application Priority Data
Mar. 13, 2025 (CN) 202510292875.1

(51) Int. Cl. H05K 5/02; H05K 5/30

(52) U.S. Cl. CPC H05K 5/0217; H05K 5/0204; H05K 5/0256; H05K 5/30

(57) ABSTRACT

An electronic device, namely a tiled electronic device, and methods for its manufacture and repair are provided. The tiled electronic device includes a frame with a plurality of guide holes and a plurality of electronic modules mounted on the frame, each electronic module having a plurality of positioning holes corresponding to the guide holes. The method for repairing the tiled electronic device involves using a fixture with a plurality of guide posts to remove a defective electronic module and install a replacement. This process includes inserting the guide posts through the frame's guide holes and into the replacement module's positioning holes, guiding the replacement module towards the frame, and securely fixing it in place.

### BACKGROUND OF THE DISCLOSURE

### 1. Field of the Disclosure

The present disclosure relates to a manufacturing method and a repairing method of an electronic device and a tiled electronic device.

### 2. Description of the Prior Art

Tiled display devices are becoming increasingly popular, however they do have significant disadvantages and restrictions. For example, because a standard tiled display device is made up of several panels, any panel failure necessitates repair or replacement, raising maintenance expenses. For example, installing and configuring a traditional tiled display device necessitates specialized workers, and the procedure is complex and time-consuming, increasing the difficulty and cost of initial setup. These shortcomings and constraints may limit the use of standard tiled display devices in some applications.

### SUMMARY OF THE DISCLOSURE

According to some embodiments, the present disclosure discloses a method of manufacturing an electronic device. The method comprises providing a frame having a plurality of guide holes; providing a fixture having a plurality of guide posts; providing an electronic module having a plurality of positioning holes; passing the plurality of guide posts through the plurality of guide holes and inserting into the plurality of positioning holes of the electronic module respectively; driving the electronic module to move towards the frame via the plurality of guide posts; and fixing the electronic module on the frame.

According to some embodiments, the present disclosure discloses a method of repairing a tiled electronic device. The method comprises providing a tiled electronic device, the tiled electronic device comprising a frame and a plurality of electronic modules, the plurality of electronic modules being disposed on the frame, the frame having a plurality of guide holes, and each electronic module having a plurality of positioning holes corresponding to the plurality of guide holes; providing a fixture having a plurality of guide posts; identifying a defective electronic module among the plurality of electronic modules; removing the defective electronic module; providing a replacement electronic module; passing the plurality of guide posts through the plurality of guide holes and inserting into the plurality of positioning holes of the replacement electronic module respectively; driving the replacement electronic module to move towards the frame through the plurality of guide posts; and fixing the replacement electronic module on the frame.

According to some embodiments, the present disclosure discloses a tiled electronic device, including a frame and a plurality of electronic modules. The frame comprises a plurality of sets of guide elements, and each set of guide elements has a plurality of guide holes. The plurality of electronic modules are disposed on the frame in a juxtaposed manner. Each electronic module comprises a reinforcement plate and an electronic panel. The reinforcement plate has a plurality of positioning holes corresponding to the plurality of guide holes respectively. The electronic panel is disposed on the reinforcement plate. A depth of each guide hole is greater than a depth of each positioning hole.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is an exploded view of an electronic device and a fixture according to an embodiment of the present disclosure.

FIG. 2 is a perspective view of the electronic device and the fixture of FIG. 1.

FIG. 3 is a side view of the electronic device and the fixture of FIG. 1.

FIG. 4 is a partial perspective view of the electronic device of FIG. 1 after one electronic module is removed.

FIG. 5 is a partial perspective view of a plurality of guide posts of the fixture passing through the guide holes of the frame of the electronic device of FIG. 1 respectively.

FIG. 6 is a cross-sectional view of the electronic device of FIG. 2 taken along the line 6-6’.

FIG. 7 is a partial schematic view of the electronic module of the electronic device in FIG. 1.

FIG. 8 is a partial schematic view of the guide post passing through the guide hole of the frame of the electronic device in FIG. 1.

### DETAILED DESCRIPTION

The present disclosure can be understood by referring to the following detailed description in conjunction with the accompanying drawings. It should be noted that, for the sake of easy understanding by the reader and the brevity of the drawings, many drawings in the present disclosure only show a part of the electronic device, and the specific elements in the drawings are not drawn according to actual proportions. In addition, the number and size of each element in the drawings are only schematic and are not intended to limit the scope of the present disclosure.

Certain terms are used throughout the specification and appended claims to refer to particular components. Those skilled in the art should understand that electronic device manufacturers may refer to the same component by different names. This document does not intend to distinguish between components that differ in name but not in function.

In the following description and claims, the words "including," "containing," "having," etc. are open-ended words, and therefore should be interpreted as "containing, but not limited to." Thus, when the description of the present disclosure uses the terms "including," "containing," and/or "having," it specifies the presence of the corresponding features, regions, steps, operations, and/or components, but does not exclude the presence of one or more other corresponding features, regions, steps, operations, and/or components.

The directional terms mentioned herein, such as "up," "down," "front," "back," "left," "right," etc., are only with reference to the direction of the drawings. Therefore, the directional terms used are for illustration and are not intended to limit the present disclosure. In the drawings, each drawing illustrates the general characteristics of the methods, structures, and/or materials used in a particular embodiment. However, these drawings should not be interpreted as defining or limiting the scope or nature encompassed by these embodiments. For example, for clarity, the relative sizes, thicknesses, and positions of various films, regions, and/or structures may be reduced or enlarged.

When a corresponding component (such as a film or region) is referred to as being "on" another component, it can be directly on the other component, or other components may exist between the two. On the other hand, when a component is referred to as being "directly on" another component, there are no components between the two. In addition, when a component is referred to as being "on" another component, the two have a vertical relationship in the vertical direction, and this component can be above or below the other component, and this vertical relationship depends on the orientation of the device.

It should be understood that when a component or film is referred to as being "connected to" another component or film, it can be directly connected to the other component or film, or intervening components or films may be present. When a component is referred to as being "directly connected to" another component or film, there are no intervening components or films. In addition, when a component is referred to as being "coupled to another component (or variations thereof)," it can be directly electrically connected to the other component, or indirectly connected (e.g., indirectly electrically connected) to the other component through one or more components.

In the present disclosure, when a component "disconnects" another component, the electrical signal cannot flow between the two components within the specified time.

The term "approximate" or "about" is generally interpreted to be within plus or minus 10% of the stated value, or interpreted to be within plus or minus 5%, plus or minus 3%, plus or minus 2%, plus or minus 1%, or plus or minus 0.5% of the stated value.

Ordinal numbers such as "first" and "second" used in the specification and claims are used to modify elements, and do not in themselves imply or represent that the element(s) have any previous ordinal number, nor do they represent the order of one element relative to another, or the order in a manufacturing process. The use of these ordinal numbers is only to clearly distinguish an element with a certain name from another element with the same name. The same terms may not be used in the claims and the specification. Accordingly, the first component in the specification may be the second component in the claims.

It should be understood that the embodiments described below can replace, reorganize, and mix features from several different embodiments to complete other embodiments without departing from the spirit of the present disclosure. Features between embodiments can be arbitrarily mixed and matched as long as they do not violate the spirit of the disclosure or conflict with each other.

In the present disclosure, the electronic device may include a display device, a light-emitting device, an antenna device, a sensing device, a medical device, a splicing device, or any combination thereof, but is not limited thereto. The display device can be a non-self-luminous display or a self-luminous display according to requirements, and can be a color display or a monochrome display according to requirements. The antenna device can be a liquid crystal type antenna device or a non-liquid crystal type antenna device, the sensing device can be a sensing device for sensing capacitance, light, thermal energy or ultrasonic waves, the medical device can be a medical testing device, and the splicing device can be a display splicing device or an antenna splicing device, but is not limited thereto. The electronic device may include electronic components, and the electronic components may include passive components and active components, such as capacitors, resistors, inductors, diodes, electrowetting elements, switching elements, dies, or chips, etc. The diode can be a die or a chip, and can include a light emitting diode (LED) or a photodiode or a varactor, but is not limited thereto. The light emitting diode may include, for example, an organic light emitting diode (OLED) or an inorganic light emitting diode, and the inorganic light emitting diode may include a mini LED, a micro LED, or a quantum dot LED, but is not limited thereto. The electro wetting element may include, for example, a Digital microfluidics (DMF) platform, an electro wetting display, an electrowetting-on-dielectric (EWOD) for lab-on-a-chip applications, but is not limited thereto. The switching element can be a transistor, and the transistor can include, for example, a top gate thin film transistor, a bottom gate thin film transistor, or a dual gate thin film transistor, but is not limited thereto. The electronic device may also include fluorescence materials, phosphor materials, quantum dot (QD) materials, or other suitable materials according to requirements, but is not limited thereto. The electronic device may have peripheral systems such as a driving system, a control system, a light source system, etc. to support the devices and components in the electronic device.

It should be noted that technical features in different embodiments described below can be replaced, reorganized, or mixed with each other to constitute another embodiment without departing from the spirit of the present disclosure.

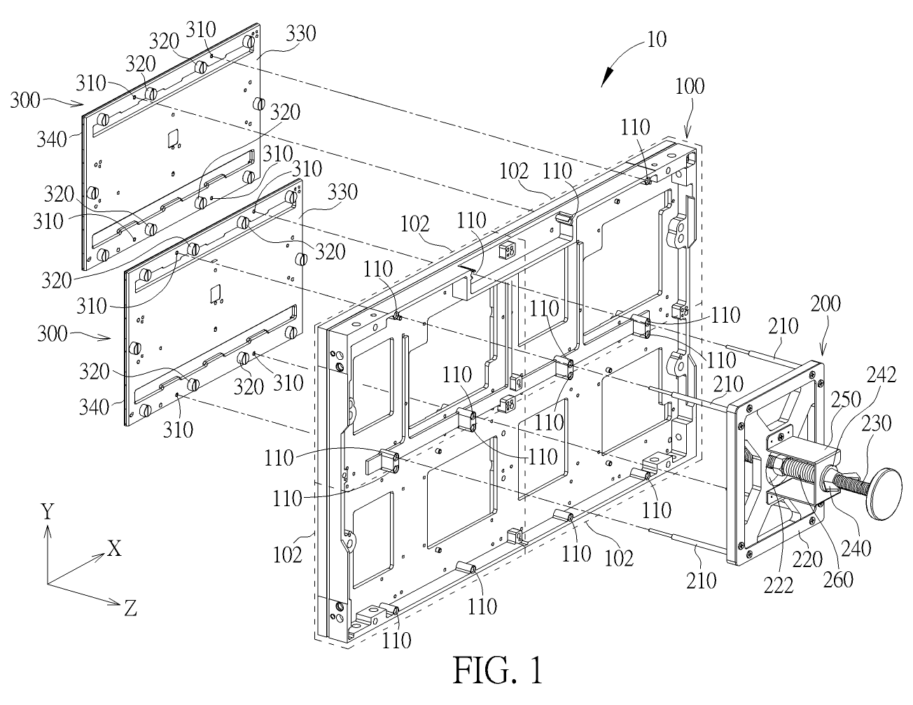

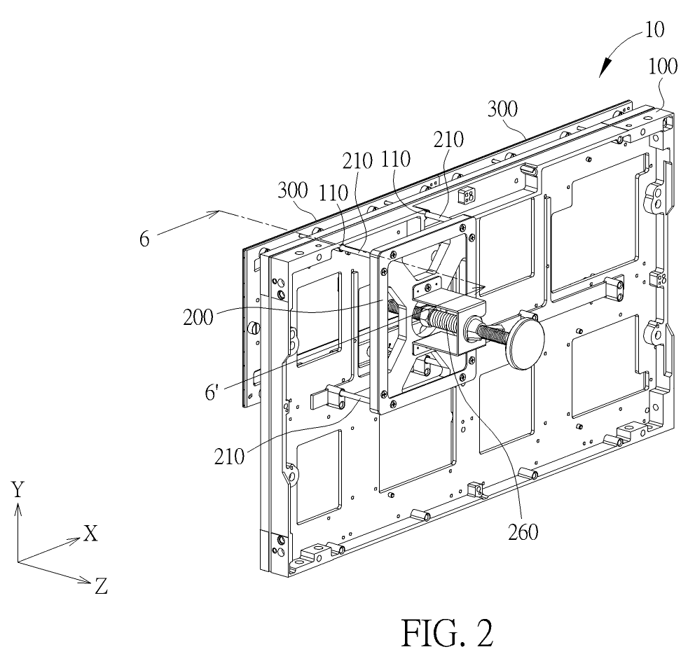

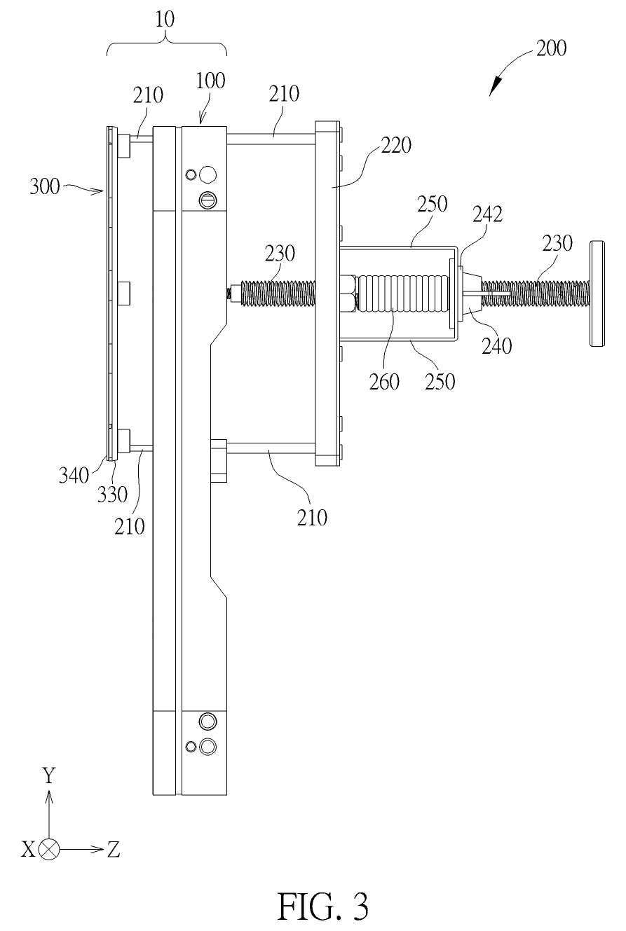

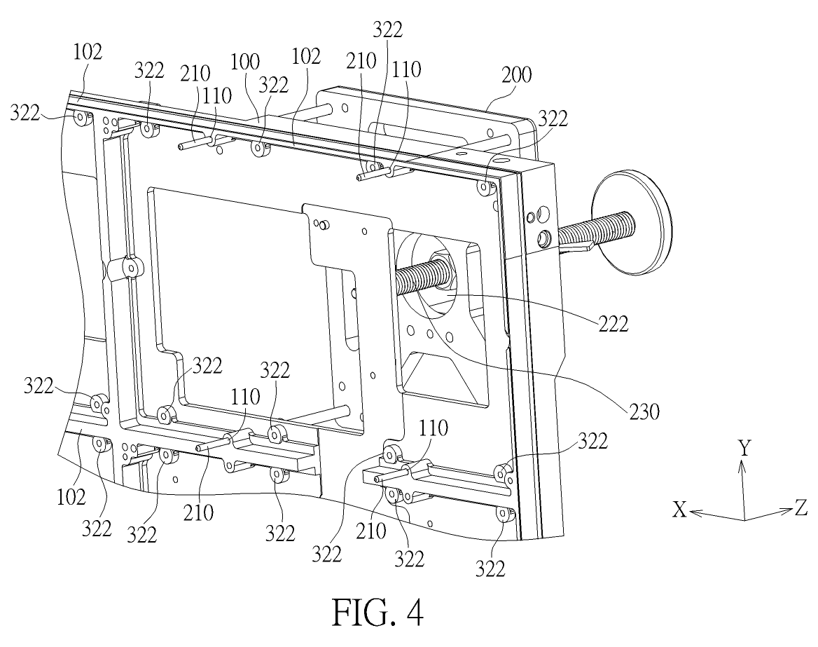

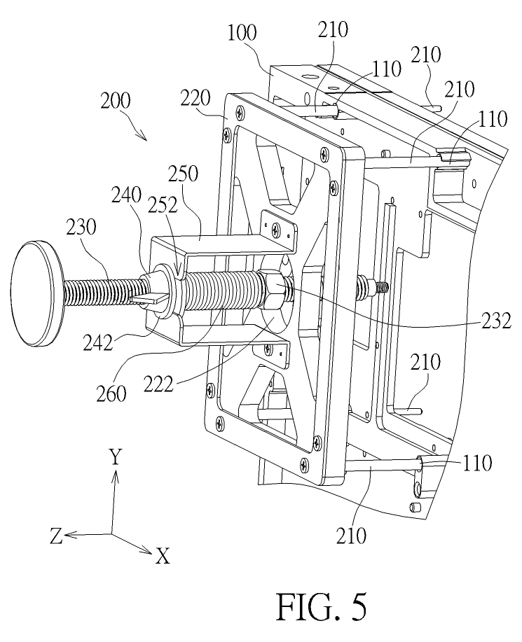

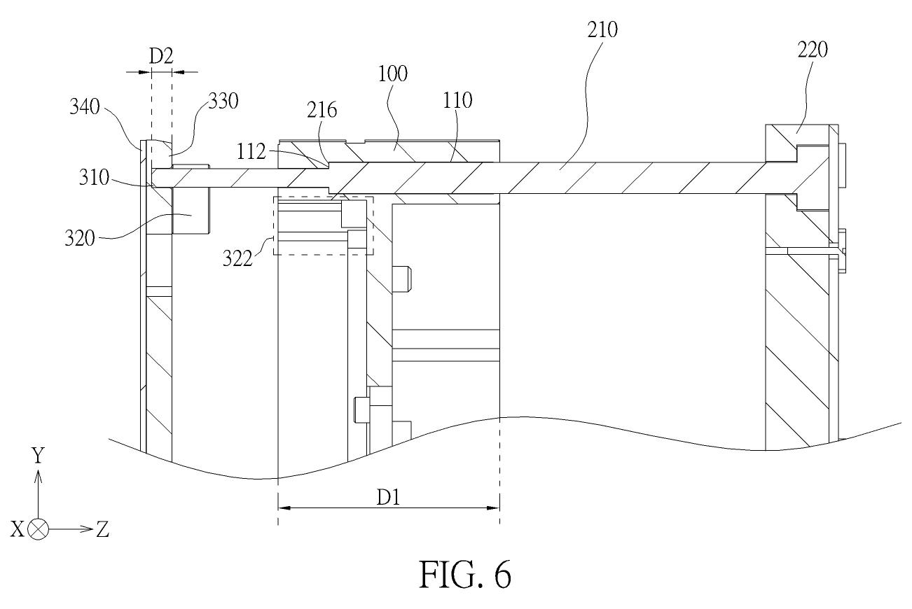

Please refer to FIGS. 1-6. FIG. 1 is an exploded view of an electronic device 10 and a fixture 200 according to an embodiment of the present disclosure. FIG. 2 is a perspective view of the electronic device 10 and the fixture 200 of FIG. 1. FIG. 3 is a side view of the electronic device 10 and the fixture 200 of FIG. 1. FIG. 4 is a partial perspective view of the electronic device 10 of FIG. 1 after one electronic module 300 is removed. FIG. 5 is a partial perspective view of a plurality of guide posts 210 of the fixture 200 passing through the guide holes 110 of the frame 100 of the electronic device 10 of FIG. 1 respectively. FIG. 6 is a cross-sectional view of the electronic device 10 of FIG. 2 taken along the line 6-6’. FIGS. 1-6 all use three axes X, Y, and Z to indicate directionality, and the directions of the three axes X, Y, and Z are different from each other. In one embodiment, the three axes X, Y, and Z may be perpendicular to each other. The electronic device 10 can be a tiled electronic device including a frame 100 and at least one electronic module 300. In this embodiment, the electronic device 10 may comprise two to four electronic modules 300. Each electronic module 300 can be disposed on the frame 100. The frame 100 comprises a plurality of guide holes 110, and each electronic module 300 comprises a plurality of positioning holes 310 corresponding to the plurality of guide holes 110.

In an embodiment of the present disclosure, the frame 100 comprises a plurality of sets of guide elements 102, and each set of guide elements 102 comprises a plurality of guide holes 110. Each set of guide elements 102 is used to dispose one electronic module 300. In this embodiment, the frame 100 comprises four sets of guide elements 102, but the present disclosure is not limited thereto. The number of sets of guide elements 102 included in the frame 100 can be other numbers. In addition, in this embodiment, each electronic module 300 can be a bezel-less display or a narrow-bezel display for displaying images, but is not limited thereto. The plurality of electronic modules 300 can be disposed on the frame 100 in a juxtaposed manner. Each electronic module 300 may comprise a reinforcement plate 330 and an electronic panel 340. The electronic panel 340 is disposed on the reinforcement plate 330. The reinforcement plate 330 comprises a plurality of positioning holes 310, and the plurality of positioning holes 310 correspond to the plurality of guide holes 110 respectively. The reinforcement plate 330 is a component for enhancing the strength and stability of the electronic module 300. It is disposed on the back of the electronic panel 340 and is tightly combined with the electronic panel 340. The reinforcement plate 330 can provide mechanical support to the electronic panel 340, prevent the electronic module 300 from deforming, and protect the internal electronic components of the electronic module 300 to a certain extent. In one embodiment, the depth D1 of each guide hole 110 is greater than the depth D2 of each positioning hole 310 (as shown in FIG. 6).

In an embodiment of the present disclosure, a manufacturing method and a repair method of a tiled electronic device are described. When any one of the electronic modules 300 is to be disposed on the frame 100, or when any electronic module 300 is to be removed from the frame 100, it can be performed by the fixture 200. The fixture 200 comprises a plurality of guide posts 210, and each guide post 210 can pass through a corresponding guide hole 110 of the frame 100. For example, when one of the electronic modules 300 of the electronic device 10 malfunctions or is defective, the plurality of guide posts 210 of the fixture 200 can be passed through the guide holes 110 corresponding to the defective electronic module 300 respectively, and the plurality of guide posts 210 of the fixture 200 are inserted into the plurality of positioning holes 310 of the defective electronic module 300. Then, the fixture 200 is operated to drive the defective electronic module 300 to move in the direction opposite to the Z-axis through the guide posts 210, so as to remove the defective electronic module 300 from the frame 100. After the defective electronic module 300 is detached and removed from the frame 100 (as shown in FIG. 4), the replacement electronic module 300 can be prepared for installation on the frame 100. When the replacement electronic module 300 is to be installed on the frame 100, if the plurality of guide posts 210 of the fixture 200 have been removed from the guide holes 110 respectively, the plurality of guide posts 210 of the fixture 200 can be passed through the corresponding guide holes 110 respectively, and the plurality of guide posts 210 of the fixture 200 are inserted into the plurality of positioning holes 310 of the replacement electronic module 300. If the plurality of guide posts 210 of the fixture 200 have not been removed from the guide holes 110 when the replacement electronic module 300 is to be installed on the frame 100, the plurality of guide posts 210 of the fixture 200 can be directly inserted into the plurality of positioning holes 310 of the replacement electronic module 300. After the plurality of guide posts 210 of the fixture 200 are inserted into the plurality of positioning holes 310 of the replacement electronic module 300, the replacement electronic module 300 can be pushed to move in the direction of the Z-axis, so as to drive the replacement electronic module 300 to move towards the frame 100 through the plurality of guide posts 210. Finally, the replacement electronic module 300 is fixed on the frame 100 to complete the process of replacing the defective electronic module 300 with the replacement electronic module 300.

In one embodiment, the fixture 200 may further comprise a substrate 220, a lead screw 230, a sleeve nut 240, a jam nut 232, a bushing 242, and a spring 260. The substrate 220 is provided with an opening 222, and the lead screw 230 can pass through the substrate 220 through the opening 222. A plurality of guide posts 210 are disposed on the substrate 220. The sleeve nut 240 is coupled to the lead screw 230 in a manner rotatable about the Z-axis, the support bracket 250 is embedded in the mounting groove 252 of the bushing 242, and the support bracket 250 and the guide post 210 are coupled to the substrate 220. The lead screw 230 can pass through the sleeve nut 240 and has a plurality of threads. The outer diameter of the lead screw 230 matches the inner diameter of the sleeve nut 240. The multi-thread design of the lead screw 230 and the sleeve nut 240 enables the sleeve nut 240 to generate a relative linear displacement between the sleeve nut 240 and the lead screw 230 when rotated. The jam nut 232 is fixed on the lead screw 230 in a locked manner with the lead screw 230, and the spring 260 is disposed between the jam nut 232 and the sleeve nut 240 in a retractable manner, and the helix of the spring 260 surrounds the outside of the lead screw 230. When the fixture 200 is used, the lead screw 230 is first fixed on the frame 100. For example, one end of the lead screw 230 can be locked into a threaded hole of the frame 100 to fix the lead screw 230 on the frame 100. After the lead screw 230 is fixed on the frame 100, the guide post 210 can be moved back and forth by rotating the sleeve nut 240. When the sleeve nut 240 is rotated, the sleeve nut 240 will move back and forth relative to the lead screw 230 (for example, the sleeve nut 240 moves in a direction parallel to the Z-axis in the illustration). For example, when the sleeve nut 240 is screwed in the direction opposite to the Z-axis, the sleeve nut 240 will compress the spring 260 through the bushing 242 and drive the substrate 220 and the guide post 210 to move in the direction opposite to the Z-axis; and when the sleeve nut 240 is screwed out in the same direction as the Z-axis, the spring 260 will drive the bushing 242, the substrate 220, and the guide post 210 to move in the same direction as the Z-axis through the elastic restoring force.

The guide post 210 is the core component of the fixture 200, and the choice of its material is crucial for the accuracy and durability of the entire assembly process. The material of the guide post 210 may include reinforced plastic, metal, stainless steel, hardened steel, ceramic, but is not limited thereto. In one embodiment, different parts of the guide post 210 may have different cross-sectional areas. For example, the cross-sectional area of the part of the guide post 210 connected to the substrate 220 is larger than the cross-sectional area of the part of the guide post 210 used to insert into the positioning hole 310. In addition, the guide hole 110 may have a first surface 112, and the guide post 210 may have a second surface 216 (as shown in FIG. 6). When the guide post 210 moves in the direction opposite to the Z-axis, through the design that different parts of the guide post 210 have different cross-sectional areas, and through the design that the guide hole 110 has different apertures in different parts, when the second surface 216 of the guide post 210 touches the first surface 112, the guide post 210 will be restricted and cannot continue to move in the direction opposite to the Z-axis.

In one embodiment, the electronic module 300 may comprise a fixing element 320 disposed on the reinforcement plate 330, and the frame 100 may comprise a fixing element 322. At least one of the fixing element 320 and the fixing element 322 may be a magnetic element. Furthermore, in one embodiment, both the fixing element 320 and the fixing element 322 are magnetic elements, and the magnetic pole of the fixing element 320 facing the +Z direction is opposite to the magnetic pole of the fixing element 322 facing the -Z direction; in another embodiment, the fixing element 320 is a magnetic element, and the fixing element 322 is made of a ferromagnetic material; and in another embodiment, the fixing element 320 is made of a ferromagnetic material, and the fixing element 322 is a magnetic element. Through the magnetic attraction between the fixing element 320 and the fixing element 322, the electronic module 300 can be attracted and fixed on the frame 100. The above-mentioned magnetic elements include magnets, Alnico, NdFeB, silicon steel sheets, Permalloy, and the above-mentioned ferromagnetic materials include iron, cobalt, nickel, and other substances that can be attracted by magnetic elements. In one embodiment, the frame 100 may be entirely made of a ferromagnetic material.

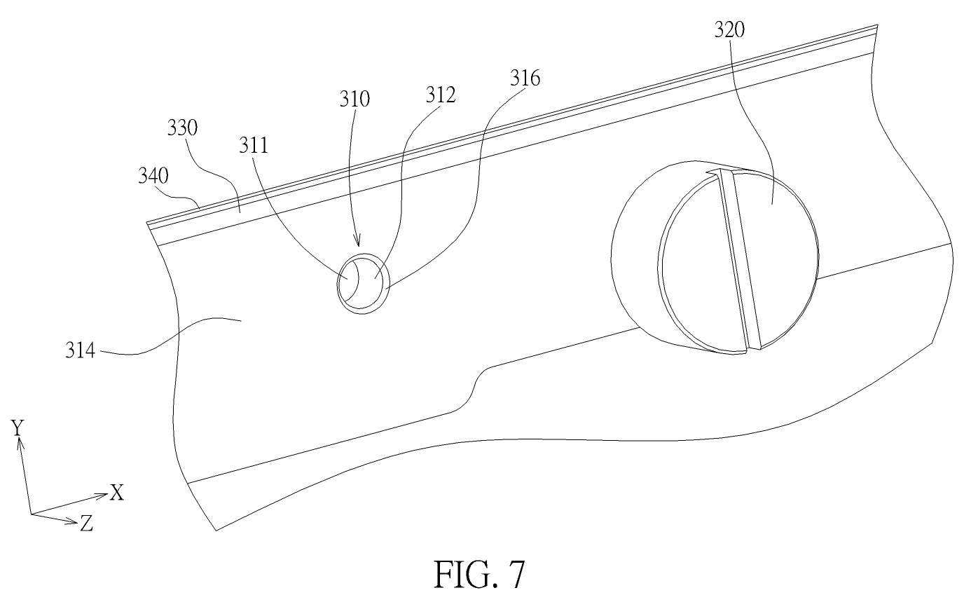

Please refer to FIG. 7, which is a partial schematic view of the electronic module 300 in FIG. 1. In this embodiment, the positioning hole 310 of the electronic module 300 is disposed on the reinforcement plate 330 and is composed of a bottom 311 and a circumference 312. The circumference 312 of the positioning hole 310 is located between the surface 314 of the reinforcement plate 330 and the bottom 311 of the positioning hole 310. The circumference 312 of the positioning hole 310 may have a chamfer 316. The design of the chamfer 316 can effectively reduce the friction during assembly, allowing the guide post 210 to be inserted into the positioning hole 310 and combined with the frame more smoothly, and improving assembly accuracy. In addition, the chamfer 316 can guide the guide post 210 to smoothly enter the positioning hole 310, reducing the risk of jamming during assembly and improving assembly efficiency.

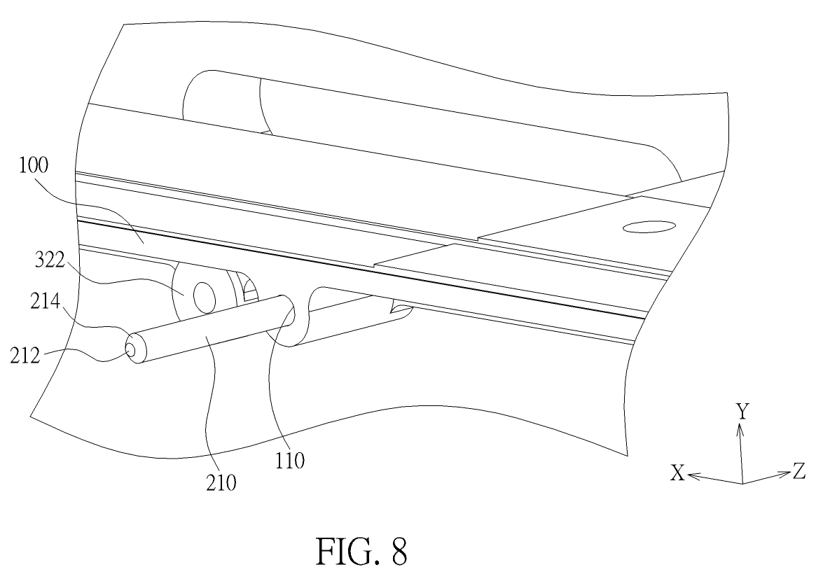

Please refer to FIG. 8, which is a partial schematic view of the guide post 210 passing through the guide hole 110 of the frame 100 of the electronic device in FIG. 1. The end surface 212 of the guide post 210 has a chamfer 214. The chamfer 214 can effectively reduce the friction when the guide post 210 is inserted into the guide hole 110, making the assembly process smoother and improving assembly accuracy. In addition, the chamfer 214 can also guide the guide post 210 to smoothly enter the guide hole 110, reducing the risk of jamming during assembly and improving assembly efficiency.

The present disclosure provides an electronic device, a manufacturing method and a repair method of a tiled electronic device, aiming to solve the problems of accuracy and efficiency in the modular assembly process of electronic devices. The electronic device is composed of a frame and at least one electronic module. The frame is provided with a plurality of guide holes, and each electronic module has a corresponding plurality of positioning holes. Through the guide posts and the fixture, the electronic module can be quickly and accurately installed and removed. Since the present disclosure adopts a modular design, the electronic module can be replaced independently, which is convenient for maintenance and upgrade. In addition, the cooperation of the guide holes and the positioning holes, and the guiding effect of the guide posts, ensure the accurate installation position of the electronic module. Through the special fixture of the present disclosure, the user can easily and quickly complete the installation and removal of the electronic module while the electronic device is in a standing state, which saves time and effort, reduces the risk of damage to the equipment, and greatly improves the convenience of maintenance.

The above descriptions are merely embodiments of the present disclosure, and any equivalent changes and modifications made in accordance with the scope of the patent application of the present disclosure shall fall within the scope of the present disclosure.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method of manufacturing an electronic device, comprising:
providing a frame having a plurality of guide holes;
providing a fixture having a plurality of guide posts;
providing an electronic module having a plurality of positioning holes;
passing the plurality of guide posts through the plurality of guide holes and inserting into the plurality of positioning holes of the electronic module respectively;
driving the electronic module to move towards the frame via the plurality of guide posts; and
fixing the electronic module on the frame.

2. The method of claim 1, wherein the fixture further comprises a substrate, a lead screw, and a sleeve nut, the lead screw passes through the substrate, the sleeve nut is coupled to the lead screw and the substrate, the sleeve nut is used for moving back and forth relative to the lead screw, and the plurality of guide posts are disposed on the substrate.

3. The method of claim 1, wherein a circumference of each of the positioning holes has a chamfer.

4. The method of claim 1, wherein an end surface of each of the guide posts has a chamfer.

5. The method of claim 1, wherein fixing the electronic module on the frame is achieved through magnetic attraction between the electronic module and the frame.

6. The method of claim 1, wherein the electronic module comprises a first fixing element, and the frame further comprises a second fixing element, at least one of the first fixing element and the second fixing element comprises a magnetic element, such that the first fixing element and the second fixing element are attracted to each other, so as to fix the electronic module on the frame.

7. The method of claim 1, wherein a depth of each guide hole is greater than a depth of each positioning hole.

8. The method of claim 1, wherein the electronic module comprises a reinforcement plate and an electronic panel disposed on the reinforcement plate.

9. The method of claim 1, wherein different parts of each of the guide posts have different cross-sectional areas, and different parts of each of the guide holes have different apertures.

10. A method of repairing a tiled electronic device, comprising:
providing a tiled electronic device, the tiled electronic device comprising a frame and a plurality of electronic modules, the plurality of electronic modules being disposed on the frame, the frame having a plurality of guide holes, and each electronic module having a plurality of positioning holes corresponding to the plurality of guide holes;
providing a fixture having a plurality of guide posts;
identifying a defective electronic module among the plurality of electronic modules;
removing the defective electronic module;
providing a replacement electronic module;
passing the plurality of guide posts through the plurality of guide holes and inserting into the plurality of positioning holes of the replacement electronic module respectively;
driving the replacement electronic module to move towards the frame through the plurality of guide posts; and
fixing the replacement electronic module on the frame.

11. The method of claim 10, wherein the fixture further comprises a substrate, a lead screw, and a sleeve nut, the lead screw passes through the substrate, the sleeve nut is coupled to the lead screw and the substrate, the sleeve nut is used for moving back and forth relative to the lead screw, and the plurality of guide posts are disposed on the substrate.

12. The method of claim 10, wherein removing the defective electronic module comprises:
passing the plurality of guide posts through the plurality of guide holes and inserting into the plurality of positioning holes of the defective electronic module respectively; and
driving the defective electronic module to move away from the frame through the plurality of guide posts.

13. The method of claim 10, wherein a circumference of each of the positioning holes has a chamfer.

14. The method of claim 10, wherein an end surface of each of the guide posts has a chamfer.

15. The method of claim 10, wherein different parts of each of the guide posts have different cross-sectional areas, and different parts of each of the guide holes have different apertures.

16. The method of claim 10, wherein the replacement electronic module comprises a first fixing element, and the frame further comprises a second fixing element, at least one of the first fixing element and the second fixing element comprises a magnetic element, such that the first fixing element and the second fixing element are attracted to each other, so as to fix the replacement electronic module on the frame.

17. A tiled electronic device, comprising:
a frame, comprising a plurality of sets of guide elements, each set of guide elements having a plurality of guide holes; and
a plurality of electronic modules, disposed on the frame in a juxtaposed manner, each electronic module comprising:
a reinforcement plate, having a plurality of positioning holes corresponding to the plurality of guide holes respectively; and
an electronic panel, disposed on the reinforcement plate;
wherein a depth of each guide hole is greater than a depth of each positioning hole.

18. The tiled electronic device of claim 17, wherein each electronic module further comprises a first fixing element disposed on the reinforcement plate, and the frame further comprises a second fixing element, at least one of the first fixing element and the second fixing element comprises a magnetic element, such that the first fixing element and the second fixing element are attracted to each other, so as to fix the electronic module on the frame.

19. The tiled electronic device of claim 17, wherein a circumference of each of the positioning holes has a chamfer.

20. The tiled electronic device of claim 17, wherein the electronic modules are fixed on the frame through magnetic attraction between the electronic modules and the frame.
